(19) United States
(12) Patent Application Publication
(10) Pub. No.: US 2006/0258035 A1
(43) Pub. Date: Nov. 16, 2006

(54) Method of repairing disconnection, method of manufacturing active matrix substrate by using thereof, and display device

(75) Inventor: Mitsuma Ooishi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC LCD TECHNOLOGIES, LTD., Kawasaki (JP)

(21) Appl. No.: 11/431,570

(22) Filed: May 11, 2006

(30) Foreign Application Priority Data
May 13, 2005 (JP) 140602/2005

(51) Int. Cl. H01L 21/00

(52) U.S. Cl. 438/30

(57) ABSTRACT

A part where a wiring is disconnected is repaired by the laser CVD method while active matrix substrates for liquid crystal display devices and organic electroluminescence display devices are being manufactured. By the laser CVD method, a conductive film is selectively formed in the part where the wiring is disconnected. Thereafter, laser light is irradiated on at least a surrounding area of the conductive film, and thus conductive fine particles remaining in the surrounding area of the conductive film are removed therefrom. As a result, a leak current and parasitic capacity can be inhibited from occurring between the part where the disconnection has been repaired and another wiring.

### BACKGROUND OF THE INVENTION

1. Field of the Invention

The present invention relates to a method of repairing disconnections of wirings formed on a substrate. Particularly, the present invention relates to a method of manufacturing an active matrix substrate using the method of repairing disconnections, and to a display device including the same.

2. Descriptions of the Prior Art

Liquid crystal display devices having thin film transistors (hereinafter referred to as “TFTs”) as switching elements have been widely used. Amorphous silicon (hereinafter referred to as “a-Si”) is chiefly used for semiconductor films of TFTs. In addition, liquid crystal display devices using polycrystalline silicon for semiconductor films of TFTs have been commercialized. Furthermore, organic electroluminescence display devices in which pixel circuits comprise with polycrystalline silicon TFTs have been developed.

In a TFT manufacturing process, if a conductor defect occurs due to a disconnection of a wiring, an active matrix display device, such as a liquid crystal display (LCD) device and an organic electroluminescence (EL) display device, becomes defective as well. Laser chemical vapor deposition (laser CVD) method has been used for repairing a disconnected wiring. The lase CVD method is the method of irradiating a repair portion with laser light in material gas, and decomposing the material gas and depositing the material gas on the repair portion to form a metallic wiring there by reacting with the laser light energy.

For example, Japanese Patent Laid-open Official Gazette No. H08-114819 (hereinafter referred to as “Patent Document 1”) has disclosed a repairing method of the disconnection generated in the intersection between a drain wiring (data signal wiring) and a gate wiring (scan signal wiring). With reference to FIG. 1A and FIG. 1B, the wiring repairing method of Patent document 1 is explained. First of all, by use of laser for cutting, two through-holes 12D and 12E for repair are made respectively at the both sides of a disconnected part 11A in a drain wiring 7A, and concurrently at the both outsides of the crossover. Subsequently, a metallic wiring 13A (a conductive film) is formed by the laser CVD method as a connecting wiring between two through-holes 12D and 12E. Incidentally, in the case of this example disclosed by Patent Document 1, coated layers 17A and 17B each with a low reflectance are provided for reducing reflection of the laser light. The defect of the wiring disconnection is repaired as shown in FIGS. 1A and 1B. In FIG. 1B, reference numerals 28A and 28B denote insulting films.

In addition, Japanese Patent Laid-open Official Gazette No. 2002-182246 (hereinafter referred to as “Patent Document 2”) has disclosed another example of a wiring repairing method using an auxiliary TFT. With reference to FIG. 2A and FIGS. 2B to 2D, descriptions will be provided for the wiring repairing method disclosed by Patent Document 2. In a case where a drain electrode 7A and a source electrode 7B of a TFT are short-circuited by a foreign substance 18, for example, laser pulses are irradiated on the drain electrode 7A. Thereby, the drain electrode 7A is severed along a long dashed double-dotted line in FIG. 2A. FIG. 2B is a cross-sectional view of a pre-repaired short-circuited area and its vicinity taken along I-I line of FIG. 2A. Subsequently, as shown in FIG. 2C, contact holes 12A and 12B for repair are made in a passivation film 8 on the drain electrode 7A and a drain electrode terminal 19 of an auxiliary TFT. The drain electrode 7A and the drain electrode terminal 19 are connected to the drain wiring (data signal wiring) 7. The contact holes 12A and 12B for repair are made by irradiating laser pulses with the third high harmonic (355 nm) or the fourth high harmonic (266 nm) of yttrium-aluminum-garnet (YAG) lasers. Thereafter, a conductive film 13 is formed by the laser CVD method, as shown in FIG. 2D. An argon gas containing a tungsten organic metal is used as a material for forming the conductive film 13. This conductive film 13 electrically connects the drain electrode 7A and the drain electrode terminal 19 of the auxiliary TFT with each other. FIG. 2A shows how the conductive film 13 electrically connects the drain electrode 7A and the drain electrode terminal 19 of the auxiliary TFT with each other. YAG laser light is irradiated on a part where a pixel electrode 10 overlaps a source electrode terminal 20 of the auxiliary TFT, and thus a contact hole 12C for repair is made in a passivation film 8, as shown in FIG. 2A. Simultaneously, the pixel electrode 10 and the source electrode terminal 20 of the auxiliary TFT are melted by the YAG laser light irradiation, and thus are joined together. Hence, the pixel electrode 10 and the source electrode terminal 20 are electrically connected with each other. Incidentally, in FIG. 2A, reference numeral 7B denotes a source electrode and reference numeral 9, a contact hole for connecting the source electrode 7B and the pixel electrode 10 with each other. In addition, in FIG. 2A, reference numeral 29 denotes a capacitive electrode wiring.

Use of the methods of forming contact holes for repair and a conductive film to repair a wiring, which have been disclosed by Patent Documents 1 and 2, makes it possible to repair the disconnection of the data signal wiring. In a case where the disconnection of the data signal wiring is repaired, it is desirable that the width of the conductive film to repair the wiring should be wider, and the film thickness thereof should be thicker, for reducing resistance of the repaired part of wiring. However, if the thickness of the conductive film to repair is too thick, this increases the stress, and accordingly decreases the adhesion of the film. As a result, it is likely that the film formed to repair the wiring may be delaminated. For this reason, a limit is imposed on the thickness of the film to repair the wiring. In addition, if the width of the film to repair wiring is formed wider, this causes a leak current between the repaired wiring and the pixel electrode. For this reason, the width of the film to repair wiring is generally approximately equal to that of the data signal wiring. However, even in a case where a part of disconnection of the wiring is repaired with these conditions, the repair causes a leak current between the repaired wiring and the pixel electrode. This is because, in the case where the disconnected wiring is repaired by the laser CVD method, conductive fine particles formed by laser CVD remain in a vicinity of the part where the disconnected wiring has been repaired. An area where these conductive fine particles are dense and connected is conductive. Accordingly, this brings about a problem of causing a leak current between the repaired wiring and the pixel electrode. As a result, this brings about a problem of causing a display defect, because the pixel electrode cannot hold proper voltage, that is, data retention characteristics is degraded.

Moreover, in a case where, for example, a data signal wiring is disconnected, the disconnection can be repaired by selectively forming a conductive film by the laser CVD method before forming the passivation film 8. After the disconnection is repaired, the passivation film 8 is formed. Thereafter, the passivation film 8 on the terminal of the switching element is selectively removed. Subsequently, a pixel electrode is formed. This method precludes a leak current from occurring between the pixel electrode and the part where the disconnected wiring has been repaired. However, even in this case, when the disconnected wiring is repaired by the laser CVD method, conductive fine particles formed by laser CVD remain in a vicinity of the part where the wiring has been repaired. Since an area where these conductive fine particles formed by laser CVD are condense and connected is conductive, additional parasitic capacity is caused between the pixel electrode and the part where the disconnected wiring has been repaired. Accordingly, this brings about a problem of causing a display defect, because the pixel electrode voltage is influenced by the repaired data signal wiring.

### SUMMARY OF THE INVENTION

With the aforementioned problems taken into consideration, the present invention has been made. The present invention provides a disconnection repairing method using a laser CVD method which controls generating of a leak current among a part where a disconnected wiring has been repaired and each of pixel electrodes and another wiring, or parasitic capacitance, and can reduce a display defect on a display device. The present invention provides a method of manufacturing an active matrix substrate, and a display device including the active matrix substrate, using the disconnection repairing method.

Furthermore, in the case where a disconnected wiring on a display device is repaired by use of the laser CVD method, the present invention provides a disconnection repairing method, a method of manufacturing an active matrix substrate, and a display device including the active matrix substrate, whereby the adhesion of the repaired wiring to the underneath films is enhanced.

A first aspect of the present invention is a method of repairing a disconnection of a wiring, which has been formed on a first insulating film, in a substrate including the wiring. The method of repairing a disconnection is characterized by including: by use of the laser CVD method, selectively forming a conductive film in an area where two ends respectively of disconnected parts of the wiring in a defective part of disconnection are to be connected with each other; and thereafter at least removing conductive fine particles which have been made by laser CVD in an area surrounding the conductive film while the conductive film is being formed. The conductive fine particles formed by laser CVD can be removed by irradiating laser light on the area surrounding the conductive film.

With regard to the method of repairing a disconnection according to the first aspect of the present invention, in a case where a second insulating film is present on the wiring inclusive of the defective part of disconnection, openings are made in portions of the second insulating film on the wiring. The portions of the second insulating film are adjacent respectively to the both sides of the defective part of disconnection. The conductive film is formed in order that the conductive film can be filled in the openings, and in order that the conductive film can connect the ends of the disconnected portions respectively at the both sides of the defective part of disconnection in the wiring.

In the case of the method of repairing a disconnection according to the first aspect of the present invention, laser light is irradiated on a surface area of a substrate on which at least the conductive film is to be formed, before the conductive film is formed. Accordingly, this makes it possible to enhance the adhesion of the conductive film, because the laser light irradiation removes dirt and cleans the surfaces of the substrate.

A second aspect of the present invention is a method of manufacturing an active matrix substrate. In the case of the method of manufacturing an active matrix substrate according to the second aspect of the present, first of all, a plurality of first wirings and a plurality of second wirings are formed on an insulating substrate with a first insulating film interposed in between. The plurality of second wirings crosses over the plurality of first wirings. Subsequently, switching elements are formed respectively at vicinities of intersections between the plurality of the first wirings and the plurality of the second wirings. Thereafter, the location of a defective part of disconnection is sought out in the second wirings. In a case where the location of the defective part of disconnection is determined in one of the second wirings, a conductive film is selectively formed, by use of the laser CVD method, in an area in which ends of disconnected portions respectively at both sides of the located defective part of disconnection in the second wiring are to be connected with each other. After that, conductive particles formed by laser CVD, which have are previously produced in an area surrounding the conductive film while the conductive film is being formed, are at least removed by irradiating laser light or the like thereon. Thereafter, pixel electrodes are formed respectively in areas on a second insulating film which are defined by the first wirings and the second wirings.

In the case of the method of manufacturing an active matrix substrate according to the present invention, the defective part of disconnection in the second wiring can be located after the pixel electrodes are formed on the second insulating film. In this case, openings which are to penetrate through the second insulating film to reach a top surface of the second wiring are made respectively in portions of the second insulating film. The portions of the second insulating film are adjacent respectively to the both sides of the defective part of disconnection. Subsequently, a conductive film is filled in the openings, and the conductive film is selectively formed on a surface of the second insulating film in an area, in which the ends of disconnected portions respectively at the both sides of the defective part of disconnection in the second wiring are to be connected with each other, by use of the laser CVD method. In the case where the conductive film is formed on the surface of the second insulating film by the laser CVD method as well, if the surface of the second insulating film is beforehand processed by laser light irradiation, this makes it possible to enhance the adhesion of the conductive film to the second insulating film.

In the case of the present invention, the following advantageous effect is brought about by the methods of repairing a disconnection, the methods of manufacturing an active matrix substrate, and display devices each including an active matrix substrate which is manufactured by use of any one of the methods of an active matrix.

The effect is that the present invention makes it possible to reduce display defect of the display devices each using the active matrix substrate, and to accordingly improve yields of the wiring repair (saving ratio).

That is because conductive fine particles formed by laser CVD remaining in the vicinity of the conductive film are removed therefrom by irradiating laser light on the vicinity of the conductive film after the conductive film is selectively formed in the defective part of disconnection by the laser CVD method. The removal of the conductive fine particles makes it possible to inhibit a leak current and parasitic capacity from occurring between the part where the disconnected wiring has been repaired and each of pixel electrodes, another wiring and/or another electrode.

### BRIEF DESCRIPTION OF THE DRAWINGS

The above and other objects, features and advantages of the present invention will become more apparent from the following detailed description when taken in conjunction with the accompanying drawings wherein;

FIG. 1A is a plan view showing the first conventional method of manufacturing an active matrix substrate;

FIG. 1B is a process cross-sectional view showing the first conventional method of manufacturing an active matrix substrate, and is a cross-sectional view of the active matrix substrate taken along the I-I line in FIG. 1A;

FIG. 2A is a plan view showing the second conventional method of manufacturing an active matrix substrate;

FIGS. 2B to 2D are process cross-sectional views showing the second conventional method of manufacturing an active matrix substrate, and are cross-sectional views of the active matrix substrate taken along the I-I wiring of FIG. 2A;

FIG. 3 is a plan view of a structure of an active matrix substrate according to the first example of the present invention, which is in the middle of being manufactured;

FIG. 4 is a plan view of a subsequent structure of the active matrix substrate according to the first example of the present invention, which is in the middle of being manufactured;

FIGS. 5A to 5C are process cross-sectional views of a method of manufacturing an active matrix substrate according to the first example of the present invention, and are cross-sectional views of the active matrix substrate taken along the I-I line in FIGS. 3 and 4;

FIGS. 6A to 6D are other process cross-sectional views of the method of manufacturing an active matrix substrate according to the first example of the present invention, and are cross-sectional views of the active matrix substrate taken along the II-II line in FIGS. 3 and 4;

FIG. 7 is a plan view of a structure of an active matrix substrate according to the second example of the present invention, which is in the middle of being manufactured;

FIGS. 8A to 8C are process cross-sectional views of a method of manufacturing an active matrix substrate according to the second example of the present invention, and are cross-sectional views of the active matrix substrate taken along the I-I line in FIG. 7;

FIGS. 9A to 9C are other process cross-sectional views of the method of manufacturing an active matrix substrate according to the second example of the present invention, and are cross-sectional views of the active matrix substrate taken along the II-II line in FIG. 7;

FIG. 10 is a plan view of a structure of an active matrix substrate according to the third example of the present invention, which is in the middle of being manufactured;

FIG. 11 is a plan view of a structure of an active matrix substrate according to the fourth example of the present invention, which is in the middle of being manufactured;

FIG. 12 is a plan view of a structure of an active matrix substrate according to the fifth example of the present invention, which is in the middle of being manufactured;

FIG. 13 is a plan view of a structure of an active matrix substrate according to the sixth example of the present invention, which is in the middle of being manufactured;

FIG. 14A is a plan view of a structure of an active matrix substrate according to the seventh example of the present invention, which is in the middle of being manufactured;

FIG. 14B is a cross-sectional view of a completed organic EL display device, which corresponds to a cross-sectional view of the active matrix substrate taken along the I-I line in FIG. 14A;

FIGS. 15A to 15D are process cross-sectional views showing an example of a method of manufacturing a liquid crystal display device, except for a step of repairing a defective part of disconnection; and

FIGS. 16A to 16C are subsequent process cross-sectional views showing the example of the method of manufacturing a liquid crystal display device, except for the step of repairing a defective part of disconnection.

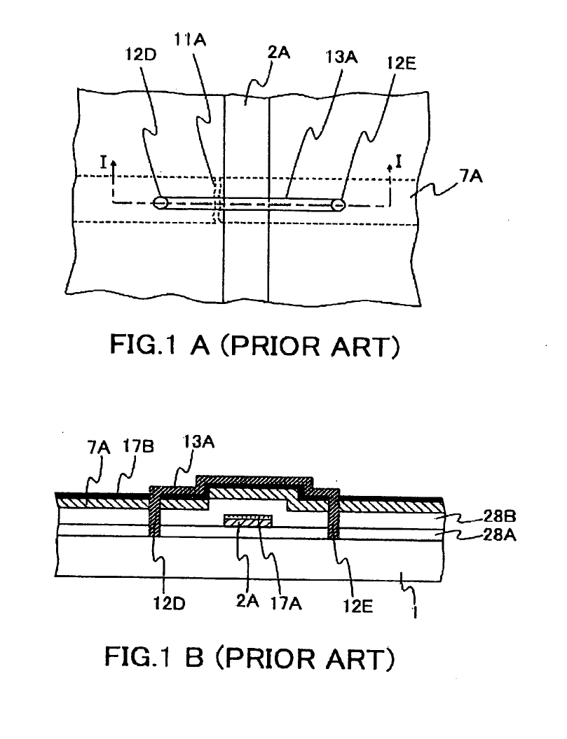

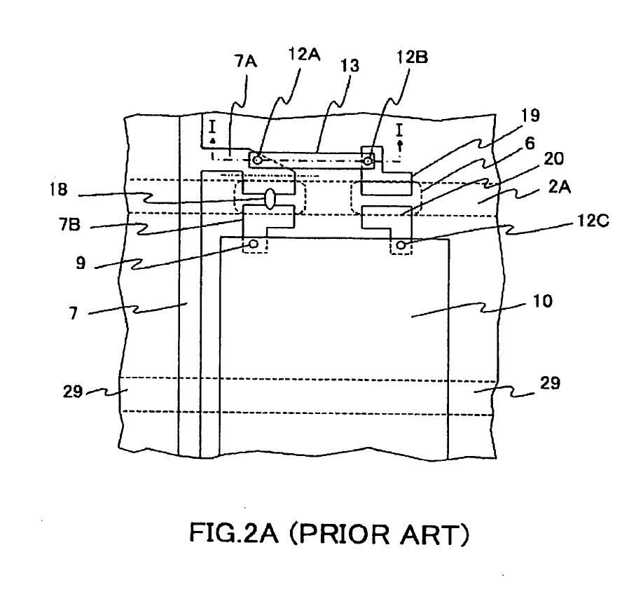

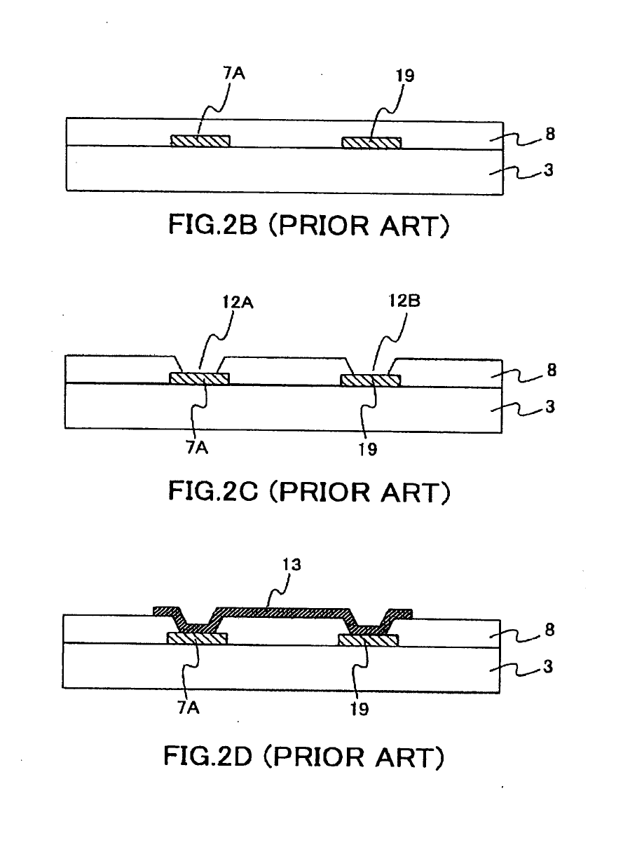

### DETAILED DESCRIPTION OF THE PREFERRED EMBODIMENT

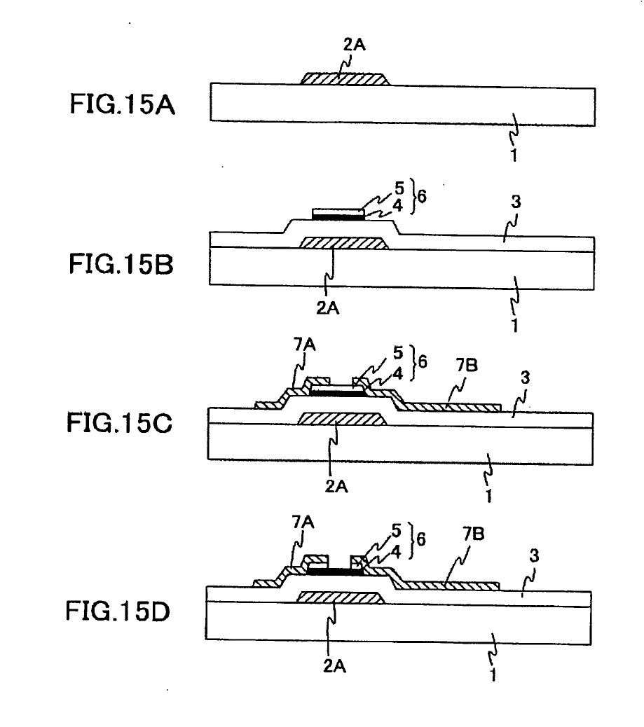

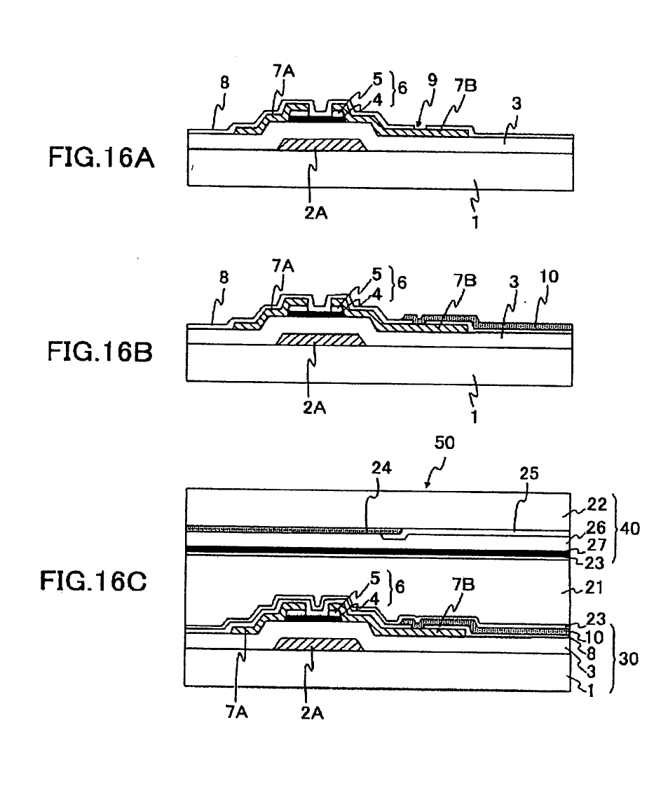

Detailed descriptions will be provided for the preferred embodiment of the present invention with reference to the drawings. For the purpose of making it easy to understand the present invention, first of all, descriptions will be provided for a method of manufacturing an active matrix liquid crystal display device, except for a step of repairing a defective part of disconnection, with reference to FIGS. 15A to 15D and 16A to 16C. FIGS. 15A to 15D and 16A to 16C shows an example of a method of manufacturing an active matrix liquid crystal display device including an active matrix substrate (TFT substrate) having TFTs which are termed as back channel etch type inverted staggered TFTs.

To begin with, a metallic film with a thickness of approximately 200 nm to 300 nm is formed on a transparent insulating substrate 1 like a glass substrate, as shown in FIG. 15A. This metallic film is patterned by the photolithography technique and the etching technique. Thereby, scan signal wirings 2 (not illustrated) are formed. This metallic film is formed by depositing any one of the following three films by a sputtering method. The first one is a laminated film obtained by laminating a molybdenum (Mo) film to a metallic film made of a metal selected from the group consisting of molybdenum (Mo), chromium (Cr), tantalum (Ta) and aluminum (Al). The second one is an alloy film essentially containing any one of molybdenum (Mo), chromium (Cr), tantalum (Ta) and aluminum (Al). The third one is a molybdenum-tungsten (MoW) alloy film. These scan signal wirings 2 also constitute gate electrodes 2A of TFTs. Subsequently, by the plasma CVD method, a gate insulating film 3 with a thickness of approximately 350 nm to 500 nm is formed of a silicon nitride (SiN) film or a laminated film obtained by laminating a SiN film to a silicon dioxide (SiO₂) film, as shown in FIG. 15B. Thereafter, a semiconductor film 4 and a semiconductor film 5 are formed. The semiconductor film 4 has a thickness of approximately 100 nm to 250 nm, and is made of amorphous silicon (hereinafter referred to as “a-Si”). The semiconductor film 5 has a thickness of approximately 20 nm to 50 nm, and is made of n⁺ amorphous silicon (hereafter referred to as “n⁺ a-Si”) obtained by doping amorphous silicon with phosphorus (P). These two films are patterned by the photolithography technique and the etching technique. Thereby, silicon islands 6 are formed.

After that, a metallic film with a thickness of approximately 200 nm to 300 nm is formed by a sputtering method, as shown in FIG. 15C. This metallic film is a single-layered film made of a metal selected from a group consisting of Mo, Cr, Ta, Titanium (Ti) and a MoW alloy. Otherwise, this metallic film is a Mo/Al/Mo laminated film. This metallic film is patterned by the lithography technique and the etching technique. Thereby, drain electrodes 7A and source electrodes 7B of the TFTs are formed. Arrangement of the drain electrodes 7A and source electrodes 7B of the TFTs is determined by operating electric potential. However, in the case of this embodiment, electrodes closer to pixel electrodes are termed as source electrodes. These drain electrodes 7A constitute data signal wirings 7 (not illustrated). Thereafter, an exposed part of each of the semiconductor films 5 are etched and removed by using the corresponding one of the source electrodes 7B and the corresponding one of the drain electrodes 7A as a mask, as shown in FIG. 15D.

Subsequently, as shown in FIG. 16A, a passivation film 8 is formed by the plasma CVD method. The passivation film 8 is a SiN film, and has a thickness of approximately 300 nm to 400 nm. Thereafter, contact holes 9 are made in the passivation film 8 near each of the TFTs by the lithography technique and the etching technique. Subsequently, an indium tin oxide (ITO) film with a thickness of approximately 40 nm to 140 nm is formed as shown in FIG. 16B. After that, the ITO film is patterned by the photolithography technique and the etching technique. Thereby, pixel electrodes 10 are formed. These pixel electrodes are connected respectively to the source electrodes 7B.

The TFT substrate 30 which has been formed in the foregoing manner and a color filter substrate 40 are faced to each other, as shown in FIG. 16C. A liquid crystal layer 21 is inserted in the gap between the TFT substrate 30 and the color filter substrate 40. Thereby, a liquid crystal panel 50 is manufactured. For example, in the case of a Twisted Nematic (TN) liquid crystal display device, an alignment film 23 of polyimide is formed over the pixel electrodes 10 of the TFT substrate 30. A rubbing process is applied to the alignment film 23. With regard to the color filter substrate 40, black matrices 24, color filters 25 and an overcoat layer 26 are formed on a transparent insulating substrate 22, such as a glass substrate. Each of the black matrices 24 is made of a Cr film. The overcoat layer 26 is formed of an acrylic resin or an epoxy resin. Thereafter, a common electrode 27 and the alignment layer 23 are formed on the overcoat layer 26. The common electrode 27 is made of an ITO film. Subsequently, for the purpose of keeping the gap between the TFT substrate 30 and the color filter substrate 40 constant, spacers (not illustrated) are arranged between the TFT substrate 30 and the color filter substrate 40. After that, the liquid crystal layer 21 is inserted in the gap between the TFT substrate 30 and the color filter substrate 40. Thereafter, the TFT substrate 30 and the color filter substrate 40 are adhered to each other by use of a sealing material (not illustrated). In addition, polarizers (not illustrated) are adhered respectively to the bottom of the TFT substrate 30 and the top of the color filter substrate 40.

Hereinafter, detailed descriptions will be provided for a method of manufacturing an active matrix substrate and a display device including the active matrix substrate according to each of the examples of the present invention.

### FIRST EXAMPLE

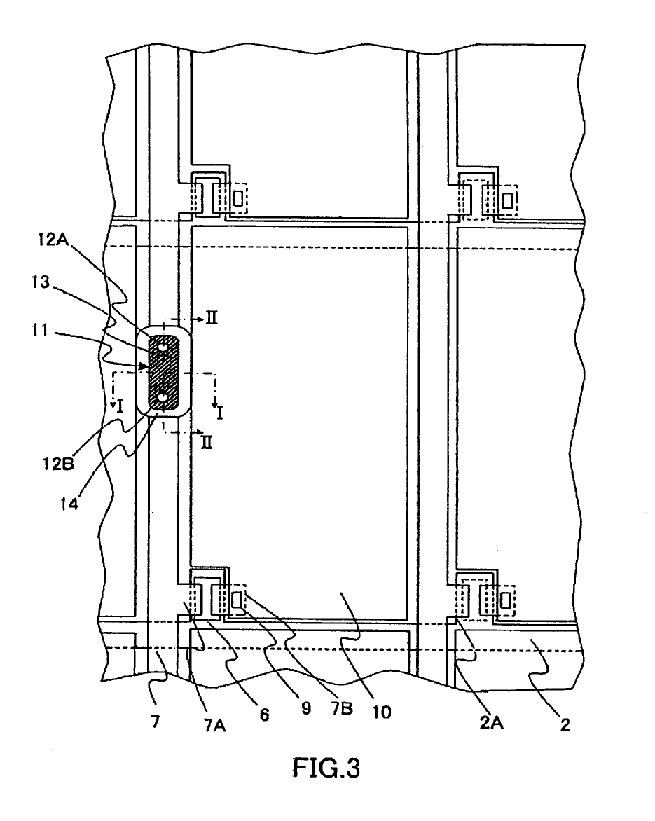

Descriptions will be provided for a method of manufacturing an active matrix substrate and a display device including the active matrix substrate according to the first example of the present invention with reference to FIGS. 3, 4, 5A to 5C, and 6A to 6D.

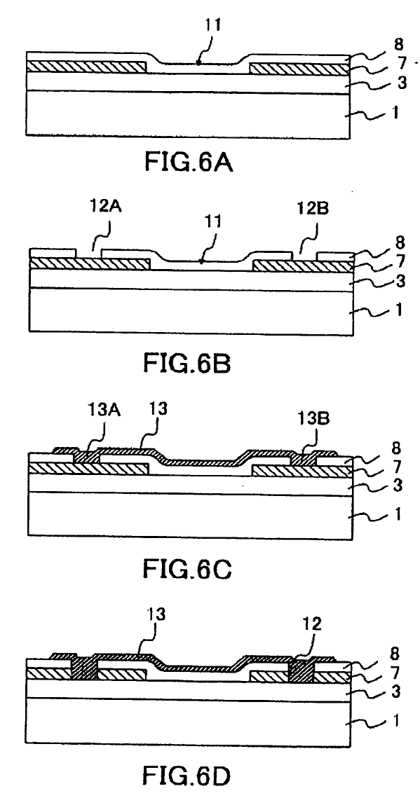

First of all, by use of the foregoing method of manufacturing an active matrix liquid crystal display device, pixel electrodes 10 of a TFT substrate are formed. After that, it is inspected whether or not each of the wirings is disconnected. In a case where a predetermined wiring (a data signal wiring 7 in this example) is disconnected, a defective part 11 of disconnection is located (see FIG. 6A). Subsequently, pulsed Nd: YLF (Neodymium:yttrium lithium fluoride) laser with a wavelength of 351 nm is irradiated thereon. Thereby, contact holes 12A and 12B for repair are made in the passivation film 8 at the two ends of the defective part 11 of disconnection as shown in FIG. 6B. Thereafter, by use of a film-forming gas made of tungsten carbonyl W(CO)₆, conductive films 13A and 13B are selectively formed respectively in the contact holes 12A and 12B for repair which have been made by the laser CVD method. In this case, a Nd: YLF laser with a wavelength of 349 nm is used. The conductive films 13A and 13B are formed in a thickness of approximately 250 nm. Subsequently, by the laser CVD method, a conductive film 13 is selectively formed between the conductive films 13A and 13B which have been selectively formed respectively in the contact holes 12A and 12B for repair. Thus, the conductive films 13A and 13B are connected with each other through the conductive film 13. The conductive film 13 is formed in a thickness of approximately 300 nm in conditions of a 20% laser transmittance and a 5 μm/sec scan speed. FIGS. 3, 5B and 6C show conditions of the defective part 11 of disconnection and its vicinity which are obtained after the conductive film 13 is formed. Incidentally, the laser transmittance is defined by a ratio (%) of the intensity of transmitted laser light to the intensity of incident laser light.

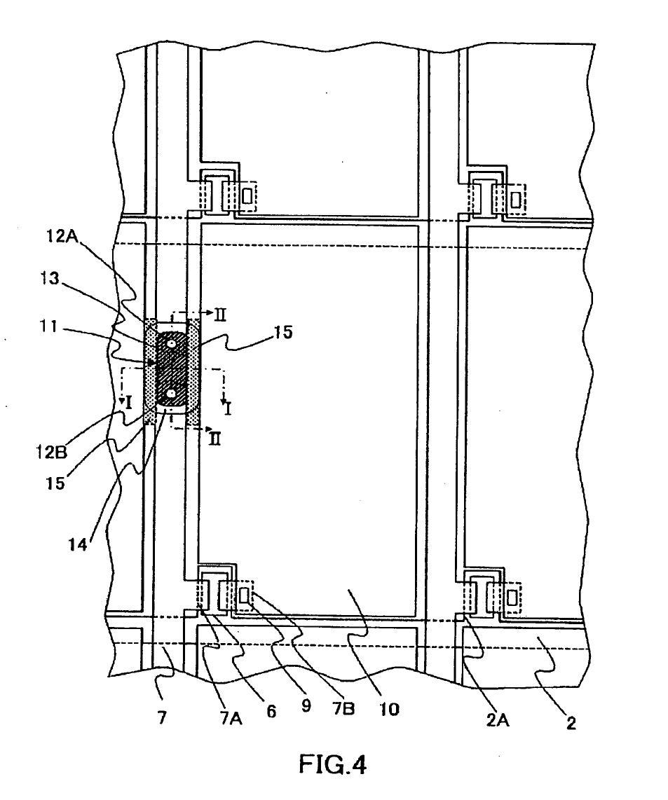

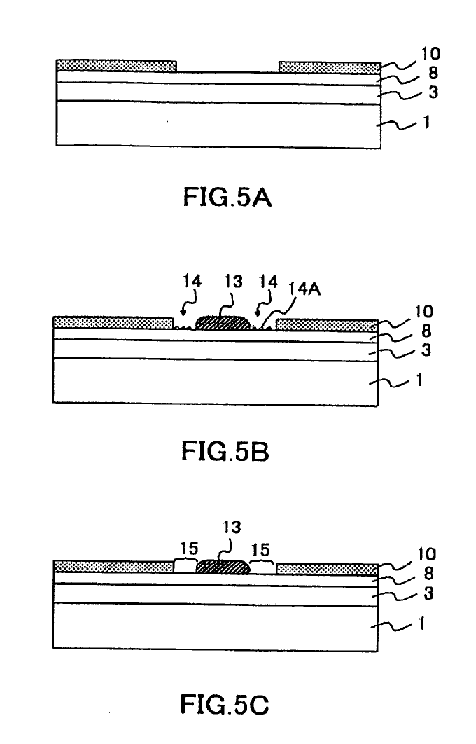

As shown in FIG. 5B, conductive fine particles 14A which are previously produced during the formation of the conductive film 13 remain in a surrounding area 14 of the conductive film 13. In the case of the aforementioned conventional example, fine particles 14A of this type bring about a problem of causing a leak current between the pixel electrode 10 and the part where the disconnection has been repaired, and a problem of accordingly causing a display defect. With these problems taken into consideration, the conductive fine particles 14A in the surrounding area 14 of the conductive film are removed without damaging the passivation film 8 in the case of this example. Specifically, a scanning irradiation is performed by use of a Nd: YLF laser whose transmittance is lower than that of the Nd: YLF laser used for making the contact holes 12A and 12B for repair. Thereby, the fine particles 14A are removed therefrom. For example, the laser light is irradiated in a scanning manner on an area 15 for laser light irradiation between the conductive film 13 and each of the pixel electrodes 10, which has been selectively formed, in conditions of a 5% laser transmittance, a 10 μm/sec scan speed and a 3 μm×3 μm slit. Accordingly, this makes it possible to remove the conductive fine particles 14A from the top of the surrounding area 14 of the conductive film without damaging the passivation film 8, as shown in FIGS. 4 and 5C.

In the case where a data signal wiring 7 is disconnected, the conductive film 13 is not formed in a way that the conductive film 13 simply connects the two ends of the defective part 11 of disconnection. Instead, in the aforementioned manner, after the conductive film 13 is formed, the laser is irradiated on the region between the conductive film 13 and its adjacent wiring or electrode (the pixel electrode 10 in this example) in the scanning manner in the predetermined conditions. Accordingly, this makes it possible to remove the conductive fine particles 14A from the top of the surrounding area 14 of the conductive film, to thus inhibit a leak current caused by the conductive fine particles. As a consequence, a display defect can be reduced.

The foregoing descriptions have been provided for the case where the conductive fine particles 14A on the surrounding area 14 of the conductive film 13 are removed therefrom by the laser light irradiation. However, it should be noted that the method of removing the conductive fine particles 14A therefrom is not limited to the laser irradiation. Any other method can be used as long as the method makes it possible to remove the fine particles 14A therefrom. Furthermore, in the case of this example which has been described above, the contact holes 12A and 12B for repair are formed in a way that the contact holes 12A and 12B for repair are made in the passivation film 8. As shown in FIG. 6D, however, contact holes 12 for repair can be formed in a way that the contact holes are made in the passivation film 8 and the respective data signal wirings 7. In this case, the conductive film 13 and the data signal wirings 7 can be electrically connected with each other respectively through side walls of the contact holes 12 for repair.

After the disconnection of the data signal wiring 7 is repaired, an active matrix liquid crystal display device is manufactured by the step which has been described above with reference to FIG. 16C.

The foregoing descriptions have been provided for the method of repairing a disconnection which is adopted for the case where the data signal wiring 7 is disconnected. This method of repairing a disconnection can be similarly applied to an arbitrary case where a wiring is formed on another wiring with an insulating film interposed between the upper wiring and the lower wiring, and thereafter a disconnection of the lower wiring is repaired.

### SECOND EXAMPLE

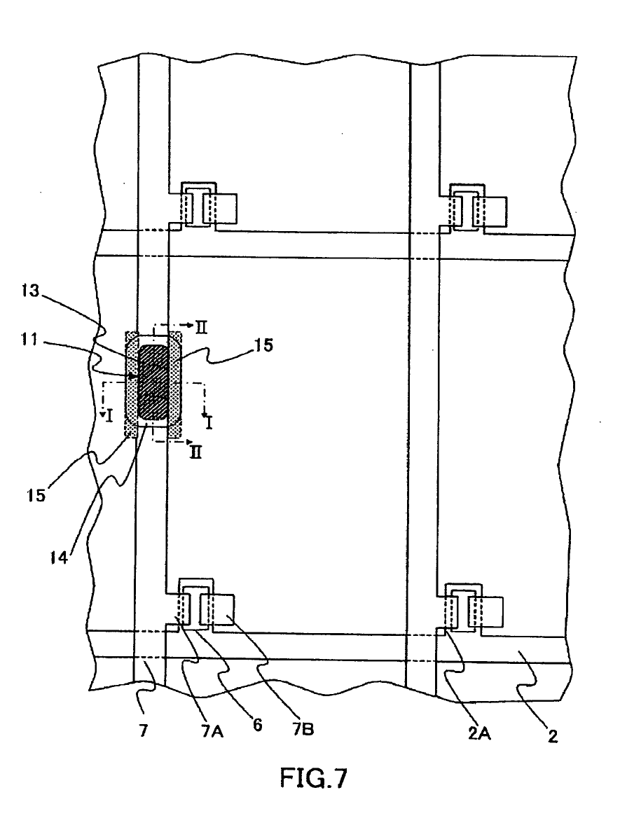

Descriptions will be provided for a method of manufacturing an active matrix substrate (TFT substrate) and a display device including the active matrix substrate according to a second example of the present invention with reference to FIGS. 7, 8A to 8C, and 9A to 9C.

In the case of the first example, a disconnection of a data signal wiring 7 is repaired after forming the pixel electrodes 10. In the case of the second example, a disconnection of a data signal wiring 7 is repaired after forming the data signal wiring 7, and before forming a passivation film 8.

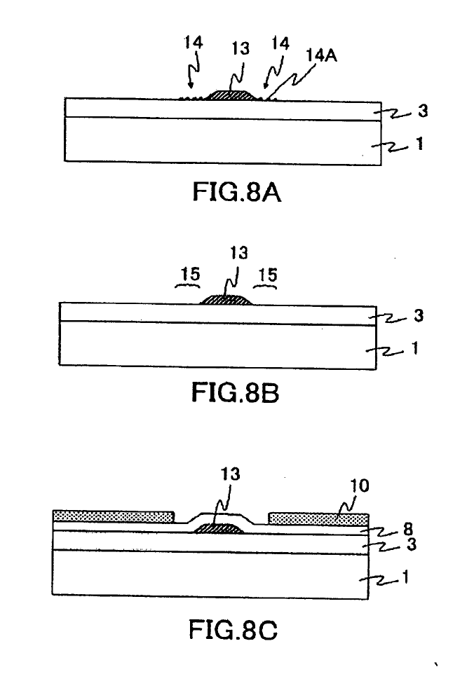

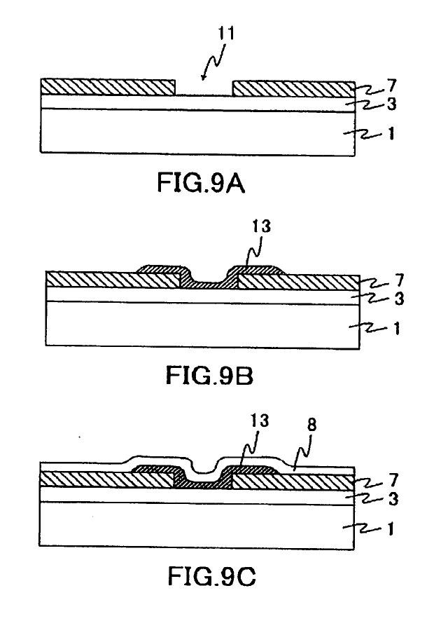

First of all, the inspection is made after the data signal wiring 7 is formed. In a case where the data signal wiring 7 is disconnected, a defective part 11 of disconnection is located (see FIG. 9A). Subsequently, as shown in FIGS. 7, 8A and 9B, a conductive film 13 is selectively formed in the defective part 11 of disconnection by the laser CVD method. Thereafter, as shown in FIGS. 7 and 8B, laser is irradiated on an area 15 for laser light irradiation in a surrounding area 14 of the conductive film 13, which has been selectively formed, without damaging a gate insulating film 3. Thereby, conductive fine particles 14A on the surrounding area 14 of the conductive film 13 are removed therefrom. Subsequently, as shown in FIGS. 8C and 9C, a passivation film 8 made of a SiN film or the like is formed by the plasma CVD method. After that, contact holes 9 (not illustrated) are made in the passivation film 8 by the lithography technique and the etching technique. Subsequently, as shown in FIG. 8C, pixel electrodes 10 made of an ITO film are formed. The active matrix liquid crystal display device is manufactured by fabricating the pixel electrodes 10 which has been described with reference to FIG. 16C.

Even in the case where the wiring is repaired before the passivation film 8 is formed, the laser is irradiated on the surrounding area 14 of the conductive film 13 in a scanning manner in predetermined conditions after the conductive film 13 is formed. Accordingly, this makes it possible to remove the conductive fine particles 14A from the top of the surrounding area 14 of the conductive film 13 without damaging the gate insulating film 3. As a result, the removing of the conductive fine particles inhibits the occurrence of a parasitic capacitance between the part where the disconnection has been repaired and another wiring, or between the part where the disconnection has been repaired and the electrode (the pixel electrode 10 in this example), thus decreases display defects.

The foregoing descriptions have been provided for the method of repairing a disconnection which is adopted for the case where the data signal wiring 7 is disconnected. It should be noted, however, that the method of repairing a disconnection can be similarly applied to a case where an arbitrary wiring, such as a scan signal wiring 2 is disconnected. In addition, the method of removing the conductive fine particles 14A therefrom is not limited to the laser irradiation as in the case of the first example. Any other method can be used as long as the method makes it possible to remove the conductive fine particles 14A therefrom.

### THIRD EXAMPLE

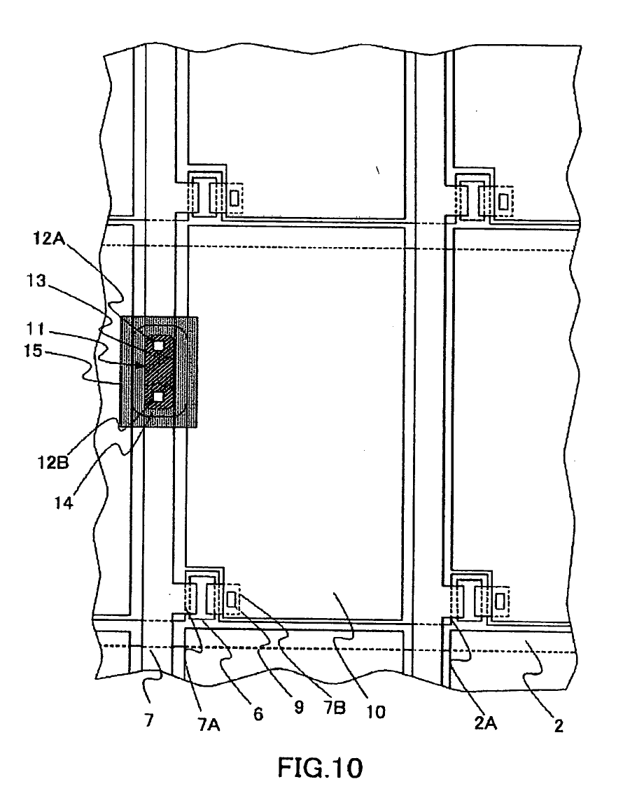

Hereinafter, descriptions will be provided for a method of manufacturing an active matrix substrate (TFT substrate) and a display device including the active matrix substrate according to a third example of the present invention with reference to FIG. 10.

In the case of the first example, the laser is irradiated on the region between the conductive film 13 and each of the pixel electrodes 10 without damaging the conductive film 13, the data signal wiring 7 and the pixel electrode 10. By reducing the power of the laser, conductive fine particles 14A on a surrounding area 14 of a conductive film 13 can be removed therefrom while inhibiting the conductive film 13, a data signal wiring 7 and a pixel electrode 10 from being damaged.

For example, as shown in FIG. 10, a Nd: YLF laser is irradiated in a scanning manner on an area 15 for laser light irradiation, inclusive of the conductive film 13 which has been selectively formed, in conditions of a 3% laser transmittance, a 10 μm/sec scan speed and a 10 μm×5 μm slit. Such laser irradiation makes it possible to remove the conductive fine particles 14A from the top of the surrounding area 14 of the conductive film 13 while inhibiting the conductive film 13, the data signal wiring 7 and the pixel electrode 10 from being damaged. This method relaxes a requirement for accuracy of a position on which the laser should be irradiated, and accordingly makes it possible to improve workability. It should be noted that, in the case of the third example, the method of removing the conductive fine particles 14A therefrom is not limited to the laser irradiation. Any other method can be used as long as the method makes it possible to remove the conductive fine particles 14A therefrom.

### FOURTH EXAMPLE

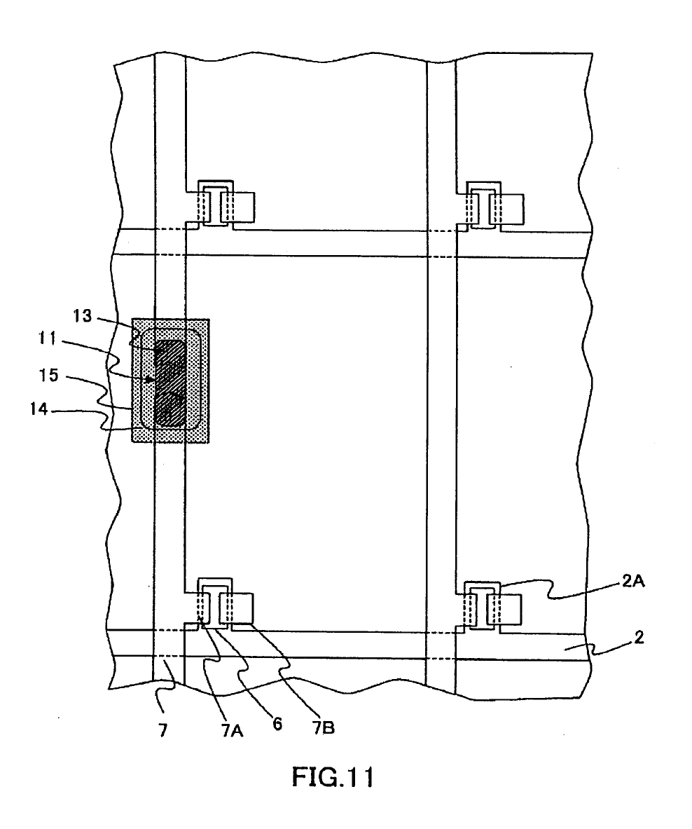

Hereinafter, descriptions will be provided for a method of manufacturing an active matrix substrate (TFT substrate) and a display device including the active matrix substrate according to a fourth example of the present invention with reference to FIG. 11. FIG. 11 is a plan view showing a configuration of the active matrix substrate according to the fourth example which is in the middle of being manufactured.

In the case of the second example, the laser is irradiated on the surroundings of the conductive film 13 without damaging the conductive film 13 and the data signal wiring 7. In the case of the fourth example, the power of the laser is reduced as in the case of the third example. Accordingly, this makes it possible to remove conductive fine particles from the top of a surrounding area 14 of a conductive film while inhibiting a conductive film 13 and a data signal wiring 7 from being damaged.

If, for example, laser light is irradiated on an area 15 for laser light irradiation, inclusive of the conductive film 13 which has been selectively formed, in the same conditions as are applied to the foregoing example, as shown in FIG. 11, this makes it possible to remove conductive fine particles 14A from the top of a surrounding area 14 of the conductive film 13 while inhibiting the conductive film 13 and the data signal wiring 7 from being damaged. This method also relaxes a requirement for accuracy of a position on which the laser should be irradiated, and accordingly makes it possible to improve workability.

It should be noted that, in the case of this example, the method of removing the conductive fine particles 14A therefrom is not limited to the laser irradiation as well. Any other method can be used as long as the method makes it possible to remove the conductive fine particles 14A therefrom. Instead of the laser irradiation, for example, by a dry-etching process slightly applied to the entire surface thereof, the conductive fine particles 14A on the surrounding area 14 of the conductive film 13 can be removed therefrom as well. Incidentally, a gas containing chlorine (Cl₂), for example, a mixed gas obtained by mixing chlorine (Cl₂), boron trichloride (BCl₃), trifluoromethane (CHF₃) and nitrogen (N₂), is used as a gas for the dry-etching process.

### FIFTH EXAMPLE

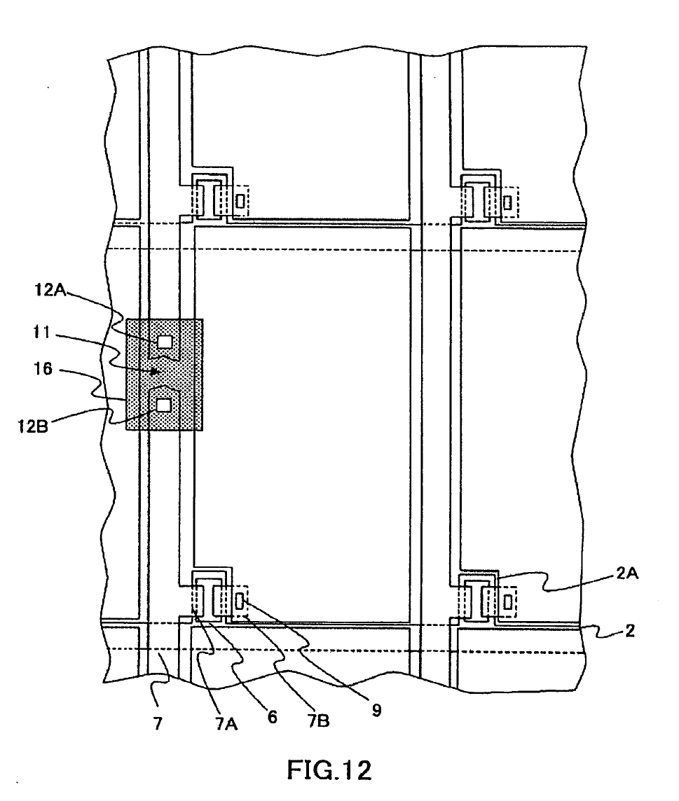

Hereinafter, descriptions will be provided for a method of manufacturing an active matrix substrate (TFT substrate) and a display device including the active matrix substrate according to a fifth example of the present invention with reference to FIG. 12. FIG. 12 is a plan view showing a configuration of the active matrix substrate according to the fifth example which is in the middle of being manufactured.

In the case of the first example, the contact holes 12A and 12B for repair are made in the passivation film 8 at the two ends of the defective part 11 of disconnection. Subsequently, the first formation of the conductive film 13 is performed in the following manner. The conductive film 13 is selectively formed by the laser CVD method in a way that the conductive film 13 covers the contact holes 12A and 12B for repair which have been formed. It is likely that the conductive film 13 formed by the laser CVD method may have its adhesion to the underneath layer which is weaker than that of a conductive film 13 formed by the sputtering method or the like. As a result, it is likely that the adhesion between the passivation film 8 and the conductive film 13 may be inhomogeneous. Accordingly, this brings about a problem that the conductive film 13 is easy to be detached from the passivation film 8, and that the reliability accordingly decreases. With these problems taken into consideration, in the case of the fifth example, laser light is irradiated on an area 16 for laser light irradiation, inclusive of an area in which a conductive film 13 is to be formed, as shown in FIG. 12, after contact holes 12A and 12B for repair are made, and before the conductive film 13 is selectively formed by the laser CVD method. Thereafter, the active matrix substrate according to the fifth example is manufactured in the same manner as the active matrix substance according to the first example is manufactured. An excimer laser, an argon laser and a He—Cd laser can be used for the laser irradiation in the case of the fifth example.

The laser light irradiation before the selective formation of the conductive film 13 in this manner makes it possible to reduce unevenness of the adhesion between the conductive film 13 and the underneath film (a passivation film 8 in this example). As a result, this makes it possible to inhibit the conductive film 13 from being detached from the underneath film, and to accordingly improve the reliability, because the laser light irradiation removes dirt and cleans the surface of the underneath film.

### SIXTH EXAMPLE

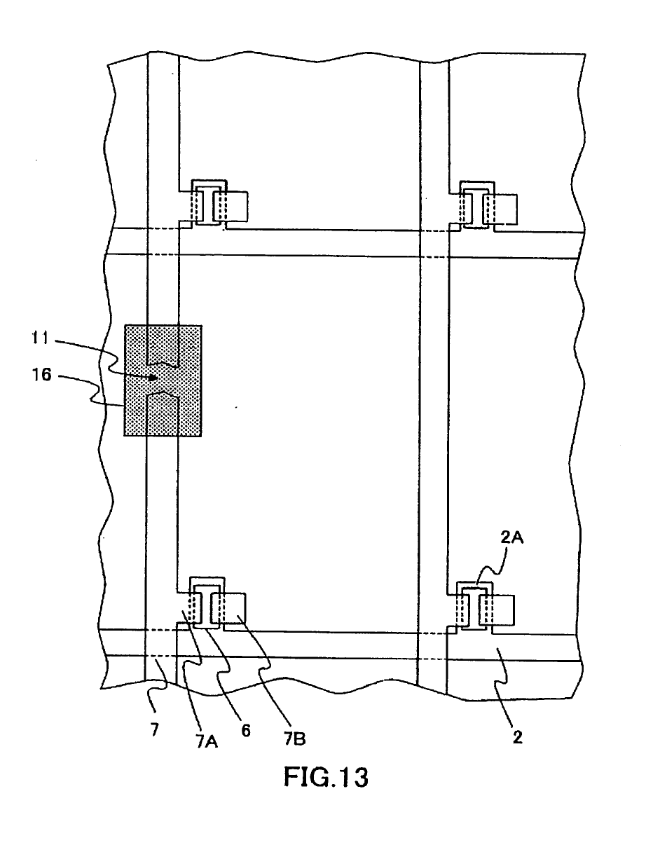

Hereinafter, descriptions will be provided for a method of manufacturing an active matrix substrate (TFT substrate) and a display device including the active matrix substrate according to a sixth example of the present invention with reference to FIG. 13. FIG. 13 is a plan view showing a configuration of the active matrix substrate according to the sixth example which is in the middle of being manufactured.

In the case of the second example, the conductive film 13 is selectively formed directly in the defective part 11 of disconnection by the laser CVD method. Like the fifth example, the second example has the problem that the adhesion among the gate insulating film 3, the data signal wiring 7 and the conductive film 13 is prone to be uneven, and that the reliability accordingly decreases. With these problems taken into consideration, in the case of the sixth example, laser light is irradiated on an area 16 for laser light irradiation, inclusive of an area in which a conductive film 13 is to be formed, as shown in FIG. 13, before the conductive film 13 is selectively by the laser CVD method. Thereafter, the active matrix substrate according to the sixth example is manufactured in the same manner as the active matrix substrate according to the second example is manufactured.

The laser light irradiation before the selective formation of the conductive film 13 in this manner makes it possible to reduce unevenness of the adhesion among the conductive film 13 and its underneath films (a gate insulating film 3 and a data signal wiring 7 in this example) As a result, this makes it possible to inhibit the conductive film 13 from being detached from the underneath films, and to accordingly improve the reliability.

### SEVENTH EXAMPLE

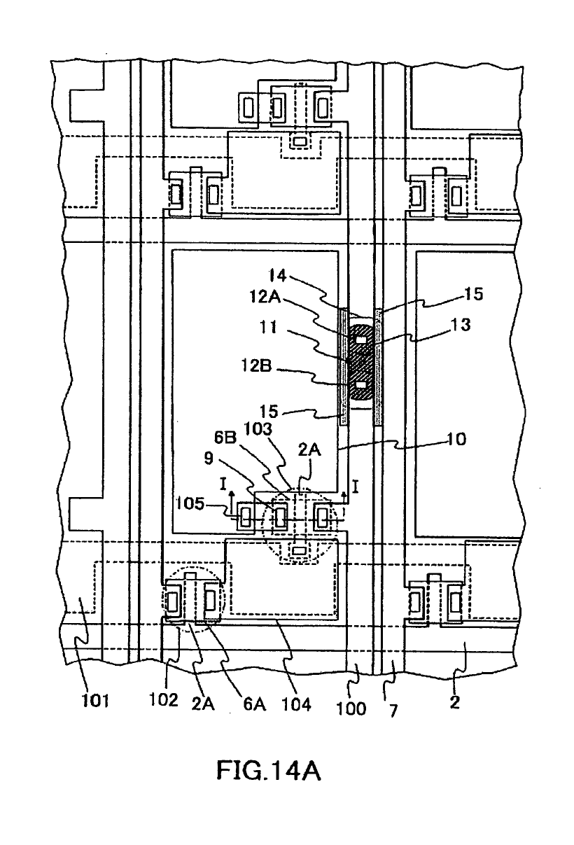

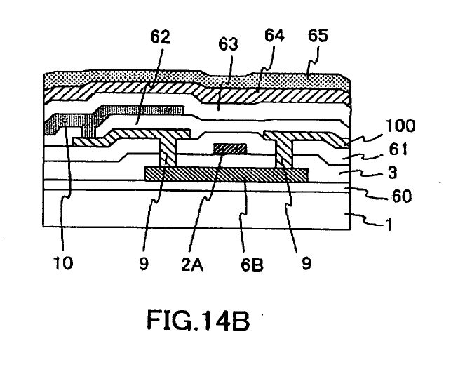

Hereinafter, descriptions will be provided for a method of manufacturing an active matrix substrate (TFT substrate) and a display device including the active matrix substrate according to a seventh example of the present invention with reference to FIG. 14A. With regard to the seventh example, descriptions will be provided for a method of repairing a defective part of disconnection in a wiring (a power supply wiring) in an organic EL display device.

Brief descriptions will be provided for the method of manufacturing a TFT substrate for an organic EL display device. First of all, a base passivation film 60 is formed on a transparent insulating substrate 1, like a glass substrate, by the plasma CVD method by using tetraethoxysilane (TEOS) The base passivation film 60 is made of SiO₂ or the like, and has a thickness of approximately 200 nm to 500 nm. Subsequently, an a-Si film with a thickness of approximately 30 nm to 70 nm is formed on the base passivation film 60 by the plasma CVD method. The a-Si film is made polycrystalline by laser annealing. Thereafter, the resultant polycrystalline Si film is patterned by the photolithography technique and the etching technique. Thus, Si islands 6A and 6B are formed. After that, a gate insulating film 3 is formed on the entire surface of the resultant substrate by the plasma CVD method. The gate insulating film 3 is made of a SiO₂ film, a laminated film obtained by laminating a SiO₂ film and a SiN film, or the like. The thickness of the gate insulating film 3 is approximately 60 nm to 150 nm.

Subsequently, a metallic film or a silicide film is formed on the gate insulating film 3 by the sputtering method. The metallic film is made of MO, Ta, Ti, Cr or the like. The silicide film is made of WSi or the like. Thereafter, the metallic film or the silicide film is patterned by the photolithography technique and the etching technique. Thus, gate electrodes 2A, scan signal wirings 2 and capacitive electrodes 101 are formed. A low concentration of phosphorus (P) is doped to the areas in the Si island 6A of each TFT 102, where are uncovered by the gate electrodes 2A, and a high concentration of phosphorus (P) is doped to the area in the Si island 6A, where are located with a distance from the gate electrodes 2A, by the photolithography technique and by ion doping. Thus, sources/drains each having a LDD (lightly doped drain) structure are formed. In addition, the areas of the Si island 6B of each TFT 103, where are uncovered by the gate electrodes 2A, are doped with boron (B) ions by the photolithography technique and by ion doping. Thus, sources/drains (not illustrated) are formed.

Thereafter, a first interlayer dielectric film 61 is deposited on the entire surface of the resultant substrate by the plasma CVD method. The first interlayer dielectric film 61 is made of a SiO₂ film, a SiN film, a SiON film or the like. Subsequently, contact holes 9 are made in the first interlayer dielectric film 61 by the photolithography technique and the etching technique. A metallic film made of Al or the like is formed on the resultant first interlayer dielectric film 61 by the sputtering method. The metallic film is patterned by the photolithography technique and the etching technique. Thus, data signal wirings 7, upper capacitive electrodes 104 and power supply wirings 100 are formed.

After that, a second interlayer dielectric film 62 is formed on the entire surface of the resultant substrate. The second interlayer dielectric film 62 is configured of a SiO₂ film, a SiN film, a SiON film, an organic resin film or the like. Second contact holes 105 are made in the second interlayer dielectric film 62 by the photolithography technique and the etching technique. An ITO film is formed on the resultant second interlayer dielectric film 62. Pixel electrodes 10 connected respectively to electrodes of the TFTs 103 are formed by applying the photolithography technique and the etching technique to the ITO film.

A defective part of disconnection in a power supply wiring 100 in a TFT substrate with the aforementioned configuration for an organic EL display device can be repaired in the same manner as the defective part of disconnection is repaired in the case of the first example. After a conductive film 13 is formed, a laser is irradiated in a scanning manner on an area 15 for laser light irradiation between the conductive film 13 and each of the pixel electrodes 10 in predetermined conditions. Accordingly, this makes it possible to remove conductive fine particles 14A from the top of the surrounding area 14 of the conductive film 13 without damaging the second interlayer dielectric film. In this case, a leak current can be inhibited from occurring between the pixel electrode 10 and the part of the power supply wiring 100 in which the disconnection has been repaired.

Furthermore, the defective part of disconnection can be repaired before the second interlayer dielectric film is formed, as in the case of the second example. In this case, a leak current can be inhibited from occurring between the part of the power supply wiring 100 in which the disconnection has been repaired and the adjacent data signal wiring 7.

After that, a publicly-known structure of the organic EL display device is constructed. For example, an organic EL layer 63 (not illustrated) is formed on the resultant substrate by vacuum evaporation. The organic EL layer 63 is configured of a hole injection layer, a hole transfer layer, a light emitting layer and an electron transfer layer. A cathode 64 (not illustrated) made of a lithium compound and Al is formed on the organic EL layer 63 by vacuum evaporation. A sealing film 65 is formed on the cathode 64. The sealing film 65 is obtained by laminating an organic resin film, a moisture absorbent layer and any one of an aluminum oxide (Al₂O₃) film, a SiN film, a SiON film and the like to each other. The moisture absorbent layer is made of calcium oxide (CaO), barium oxide (BaO) or the like. The aluminum oxide (Al₂O₃) film, the SiN film, the SiON film and the like are formed by the plasma CVD method and/or the sputtering method. FIG. 14B is a cross-sectional view of a chief part of a completed organic EL display device.

It should be noted that, in the case of this example, the method of removing the conductive fine particles 14A therefrom is not limited to the laser irradiation. Any other method can be used as long as the method makes it possible to remove the conductive fine particles 14A therefrom. The foregoing descriptions have been provided for the method of repairing a power supply wiring 100 in the case where the power supply wiring 100 is disconnected. By use of the same method, however, an arbitrary wiring, such as a data signal wiring 7, a scan signal wiring 2 and a capacitive electrode wiring 101, can be repaired in a case where the arbitrary wiring is disconnected. In addition, if the power of the laser is reduced as in the cases of the third and the fourth examples, the laser can be irradiated on a wider area. Moreover, if, as in the cases of the fifth and the sixth examples, the laser is irradiated thereon before the conductive film 13 is formed, this makes it possible to enhance the adhesion among the conductive film 13 and the underneath films.

In the case of each of the first to the sixth examples, the TFTs are formed of a-Si. However, the TFTs may be formed of polycrystalline silicon. Furthermore, in the case of each of the first to the seventh examples, switching elements of another type may be formed. Moreover, the present invention can be applied to staggered (top gate) structure TFTs as well, although the first to sixth examples have been described citing the inverted staggered (bottom gate) structure TFTS. In the case of the staggered (top gate) TFTs, the gate electrodes are arranged respectively over the source/drain electrodes with an a-Si film in between. In the case of the inverted staggered (bottom gate) structure TFTs, the source/drain electrodes are arranged respectively over the gate electrodes with an a-Si film in between.

The present invention can be applied to an arbitrary substrate including a wiring problematic with a leak current, and parasitic capacity, between the wiring and its adjacent wirings, and can be applied to an arbitrary device using the arbitrary substrate.

While this invention has been described in connection with a certain preferred embodiment, it is to be understood that the subject matter encompassed by way of this invention is not to be limited to those specific embodiments. On the contrary, it is intended for the subject matter of the invention to include all alternative, modification and equivalents as can be included within the spirit and scope of the following claims.

What is claimed is:

1. A method of repairing a disconnection of a wiring formed on a first insulating film in a substrate having the wiring, comprising:
by use of a laser CVD method, selectively forming a conductive film in an area in which ends of disconnected portions respectively at both sides of a defective part of disconnection in the wiring are to be connected with each other; and
at least removing conductive fine particles which are previously produced in an area surrounding the conductive film while the conductive film is being formed.

2. The method of repairing a disconnection of a wiring according to claim 1, wherein the conductive fine particles which are previously produced in the area surrounding the conductive film are removed by any one selected from a method of irradiating laser light on the area surrounding the conductive film and a method of causing the area surrounding the conductive film to undergo a dry etching process.

3. The method of repairing a disconnection of a wiring according to claim 1,
wherein a second insulating film is present on the wiring including the defective part of disconnection, and
wherein the conductive film is formed in order that the conductive film can connect the ends of the disconnected portions respectively at the both sides of the defective part of disconnection in the wiring with each other, by forming the conductive film on the second insulating film on the wiring, and by filling the conductive film in openings which have been made in portions of the second insulating film, the portions being adjacent respectively to the both sides of the defective part of disconnection.

4. The method of repairing a disconnection of a wiring according to claim 1, further comprising a step of processing at least a surface area of the substrate, on which the conductive film is to be formed, by laser light irradiation before the conductive film forming step.

5. A method of manufacturing an active matrix substrate, comprising:
forming a plurality of first wirings on an insulating substrate;
forming a first insulating film on the resultant insulating substrate in a way that the first insulating film covers the plurality of first wirings;
forming a plurality of second wirings crossing over the plurality of first wirings on the first insulating film, and switching elements respectively at vicinities of intersections between the plurality of first wirings and the plurality of second wirings;
locating a defective part of disconnection in one of the second wirings;
by use of a laser CVD method, selectively forming a conductive film in an area in which ends of disconnected portions respectively at both sides of the located defective part of disconnection in the second wiring are to be connected with each other;
at least removing conductive fine particles which are previously produced in an area surrounding the conductive film while the conductive film is being formed;
forming a second insulating film on an entire surface of the resultant insulating substrate, including the switching elements and the data signal wirings; and
forming pixel electrodes respectively in areas on the second insulating film which are defined by the first wirings and the second wirings.

6. The method of manufacturing an active matrix substrate according to claim 5, wherein the conductive fine particles are removed by irradiating laser light thereon.

7. The method of manufacturing an active matrix substrate according to claim 5, further comprising:
processing at least a surface of the defective part of disconnection by laser light irradiation before the conductive film forming step.

8. The method of manufacturing an active matrix substrate according to claim 5, wherein the switching elements are thin film transistors each including a semiconductor film made of any one selected from the group consisting of amorphous silicon and polycrystalline silicon.

9. A liquid crystal display device comprising:
an active matrix substrate which is manufactured by use of the method of manufacturing an active matrix substrate according to claim 5.

10. An organic electroluminescent display device comprising:
an active matrix substrate which is manufactured by use of the method of manufacturing an active matrix substrate according to claim 5.

11. A method of manufacturing an active matrix substrate, comprising:
forming a plurality of first wirings on an insulating substrate;
forming a first insulating film on the resultant insulating substrate in a way that the first insulating film covers the plurality of first wirings;
forming a plurality of second wirings crossing over the plurality of first wirings on the first insulating film, and switching elements respectively at vicinities of intersections between the plurality of first wirings and the plurality of second wirings;
forming a second insulating film on an entire surface of the resultant insulating substrate including the switching elements and the second wirings;
forming pixel electrodes respectively on areas in the second insulating film which are defined by the first wirings and the second wirings;
locating a defective part of disconnection in one of the second wirings;
making openings, which are to penetrate through the second insulating film on the second wiring to reach a top surface of the second wiring, respectively in portions of the second insulating film, the portions being adjacent respectively to both sides of the defective part of disconnection;
filling a conductive film in the openings, and selectively forming the conductive film on a surface of the second insulating film in an area, in which ends of disconnected portions respectively at both sides of the defective part of disconnection in the second wiring are to be connected with each other, by use of a laser CVD method; and
at least removing conductive fine particles which are previously produced on the surface of the second insulating film in an area surrounding the conductive film while the conductive film is being formed.

12. The method of manufacturing an active matrix substrate according to claim 11, wherein the openings are made by laser irradiation.

13. The method of manufacturing an active matrix substrate according to claim 11, wherein the conductive fine particles are removed by irradiating laser light thereon.

14. The method of manufacturing an active matrix substrate according to claim 11, further comprising:
a step of processing a surface area of the second insulating film, on which the conductive film is to be formed, by laser light irradiation before the conductive film forming step.

15. The method of manufacturing an active matrix substrate according to claim 11, wherein the switching elements are thin film transistors each including a semiconductor film made of any one selected from the group consisting of amorphous silicon and polycrystalline silicon.

16. A liquid crystal display device comprising:
an active matrix substrate which is manufactured by use of the method of manufacturing an active matrix substrate according to claim 11.

17. An organic electroluminescence display device comprising:
an active matrix substrate which is manufactured by use of the method of manufacturing an active matrix substrate according to claim 11.
